(19) United States
(12) Patent Application Publication
(10) Pub. No.: US 2026/0328226 A1
(43) Pub. Date: Oct. 22, 2026

(54) OSCILLATING ELECTROHYDRODYNAMIC CONDUCTION PUMP

(71) Applicant: Worcester Polytechnic Institute, Worcester, MA (US)

(72) Inventors: Jamal S. Yagoobi, Hopkinton, MA (US); Alexander Castaneda, Worcester, MA (US); Nathaniel J. O'Connor, Worcester, MA (US)

(21) Appl. No.: 19/650,810

(22) Filed: Apr. 17, 2026

Related U.S. Application Data
(60) Provisional application No. 63/790,325, filed on Apr. 17, 2025.

(51) Int. Cl. F04F 99/00; H10W 40/47

(52) U.S. Cl. CPC F04F 99/00; H10W 40/47

(57) ABSTRACT

A bi-directional, electrohydrodynamic (EHD) conduction pumping approach, optionally with dielectrophoresis (DEP), applies an oscillating electric signal to EHD electrodes for fluid management of EHD directed (pumped) fluid. A flexible substrate supporting an array of alternating voltage (power) and ground electrodes provides a directional fluid control of a dielectric fluid, particularly for cooling electronics based on heat transfer to the dielectric fluid. Planar orientation and spacing of alternating electrodes on a generally planar substrate allows implementation adjacent to electronic heat sources for fluidic pumping control from a control circuit for oscillating a voltage signal to the electrodes and controlling an electrical field induced flow.

### RELATED APPLICATIONS

This patent application claims the benefit under 35 U.S.C. § 119 (e) of U.S. Provisional Patent App. No. 63/790,325, filed Apr. 17, 2025, entitled “OSCILLATING ELECTROHYDRODYNAMIC CONDUCTION PUMP,” incorporated herein by reference in entirety.

### STATEMENT OF FEDERALLY SPONSORED RESEARCH AND DEVELOPMENT

This invention was made with government support under contract No. 80NSSC19K1170 and 80NSSC22K0676 awarded by the National Aeronautics and Space Administration (NASA). The government has certain rights in the invention.

### BACKGROUND

Modern electronic devices generate substantial heat due to a concentration of many electrical components in an integrated circuit of a relatively small size. As modern semiconductor technology improves to result in increasing circuit density, the number of heat-producing circuit elements occupy a smaller footprint. An electron flow through a circuit generates heat, and therefore an increase in circuit density produces a corresponding increase in the heat generated. Modern semiconductors, for example, require fluidic cooling, either by forced air fans, or by liquid based cooling, which is becoming more prevalent due to the increased heat transfer capabilities of liquid.

Conventional thermal management approaches for electronics, computer and storage mediums are typically comprised of technologies such as heat pipes, two-phase loops, or phase-changing materials, or steady state thermoelectric coolers to dissipate heat from electronics. These systems, despite their ability to transfer heat, are often met with challenges such as overcoming mechanical deterioration, low efficiency, and are often limited to passive thermal management methods.

### SUMMARY

A bi-directional, electrohydrodynamic (EHD) conduction pumping approach, optionally with dielectrophoresis (DEP), applies an oscillating electric signal to EHD electrodes for fluid management of EHD directed (pumped) fluid. A flexible substrate supporting an array of alternating voltage (power) and ground electrodes provides a directional fluid control of a dielectric fluid, particularly for cooling electronics based on heat transfer to the dielectric fluid. Planar orientation and spacing of alternating electrodes on a generally planar substrate allows implementation adjacent to electronic heat sources for fluidic pumping control from a control circuit for oscillating a voltage signal to the electrodes and controlling an electrical field-induced flow.

Configurations herein are based, in part, on the observation that cooling mechanisms are often employed for heat transfer from electronics and similar heat generating appliances and contexts. Unfortunately, conventional approaches to cooling typically employ mechanical systems that rely on condensation and evaporation of a cooling fluid with associated compressors for forcing a phase change (gaseous to liquid) often driven with a fan-forced heat exchange medium. These conventional mechanical approaches employ motors and other moving parts having maintenance constraints and failure modes.

Electrohydrodynamic (EHD) conduction pumping is a low power and non-mechanical method to pump fluids for thermal management. In addition to these advantages, EHD is also simple in design and is controllable, as it can be integrated into complex and programmable scenarios for optimal thermal management. Configurations herein substantially overcome the shortcomings of conventional approaches by providing an EHD pumping mechanism invoking electrically driven fluid motion using ion-dissociation and recombination in a dielectric fluid in a flexible substrate adaptable to deployment constraints with minimal power and no moving parts prone to wear.

In further detail, configurations herein provide an electrohydrodynamic fluid transport device including a plurality of voltage electrodes at least one ground electrode, such that the ground electrodes and voltage electrodes are aligned in an alternating sequence along a fluidic pumping path. An oscillation control circuit is configured for applying an oscillating voltage signal to the voltage electrodes at a predetermined frequency. This method of electrohydrodynamic fluid transport an alternating arrangement of voltage electrodes and ground electrodes disposed in the fluidic pumping path, and applies a voltage level in an oscillating manner to the voltage electrodes at a predetermined frequency.

### BRIEF DESCRIPTION OF THE DRAWINGS

The foregoing and other objects, features and advantages of the invention will be apparent from the following description of particular embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a diagram of electrohydrodynamic (EHD) force generation as employed in configurations herein;

FIG. 2 is a schematic diagram of spacing of electrodes as in FIG. 1;

FIGS. 3A-3E shows EHD electrodes on various substrate arrangements;

FIGS. 4A-4B show heat flux suitable for electronics cooling using an EHD approach as in FIGS. 1-3; and

FIGS. 5A-5B show a schematic of a bidirectional EHD pump using electrodes as in FIGS. 1-4B.

### DETAILED DESCRIPTION

Electrohydrodynamics (EHD) is the phenomenon in which electric fields interact with fluids to produce motion. EHD has been proven as a method of liquid film pumping, heat transfer enhancement, and mixing. An EHD body force can be defined by:

$${F}_{EHD} = {ρ}_{e} E - \frac{1}{2} {E}^{2} ∇ ε + \frac{1}{2} ∇ [ {E}^{2} {ρ ( \frac{\partial ε}{\partial ρ} )}_{T} ] \qquad ( Eq . 1.1 )$$

where ρₑ is the net charge density, E is the applied electric field, ρ is the fluid density, and ε is the fluid electric permittivity. The first term in this expression is referred to as the Coulomb force density, which exists as free charges are present in a dielectric fluid under the influence of an electric field. This term is the main driving force for EHD conduction pumping. The remaining two terms are known as the dielectrophoretic (DEP) force and the electrostriction force. The DEP force exists in the presence of a large gradient in electrical permittivity, which is typically due to the presence of a liquid-vapor interface or in the presence of a large enough temperature gradient. The electrostriction term is typically negligible for EHD conduction pumping, as the working liquid is considered incompressible. In configurations herein, the Coulomb force and DEP force are the main driving factors for electrically-driven thermal management based on a pumped or directed cooling fluid.

EHD conduction pumping harnesses the behavior of ionic species in a dielectric fluid under the application of an electric field. Dielectric fluids contain positive and negative ionic species, sometimes referred to as impurities, that constantly dissociate and recombine at an equilibrium rate. This equilibrium rate exists in the presence of low enough electric fields, however, when a high enough field is present, the rate of dissociation exceeds that of recombination due to field-enhanced dissociation. This creates non-equilibrium charge accumulation near the electrodes. These layers, henceforth referred to as heterocharge layers, have the opposite polarity of the electrode they form over (i.e., a negative heterocharge layer forms over the positive electrode). If the electrodes are equal in size, this will essentially cause local circulation with no net flow. However, if the electrodes are designed to be asymmetric, a net Coulomb force, and thus, a net fluid flow is generated. The transient evolution and morphology of these heterocharge layers is of particular interest, as it has a notable effect on pumping. Conduction pumping operates without the need for additional free charges, and does not experience significant fluid degradation, making it desirable for longer term operational environments. In contrast to induction pumping, the necessary power supplies are simply DC voltage sources. Similarly, the design of conduction pumps is very simple, and can be scaled down from the macro-scale to the micro-scale without sacrificing performance.

Dielectric fluids in general are electrical insulating liquids with high dielectric strength often used to cool and insulate high-voltage equipment, typically take the form of mineral oils, synthetic esters, and silicone-based options. In an example configuration, a primary working fluid is HFE 7100 (often referred to as Novec 7100) and is a dielectric fluid. As mentioned, a dielectric fluid is comprised of ionic species that dissociate and recombine at an equilibrium rate under normal conditions. However, in the presence of a strong applied electric field, the rate of dissociation will exceed that of recombination, resulting in charge accumulation. Heterocharge layers form over these electrodes and produce fluid motion, directly contributing to the Coulomb force term described earlier.

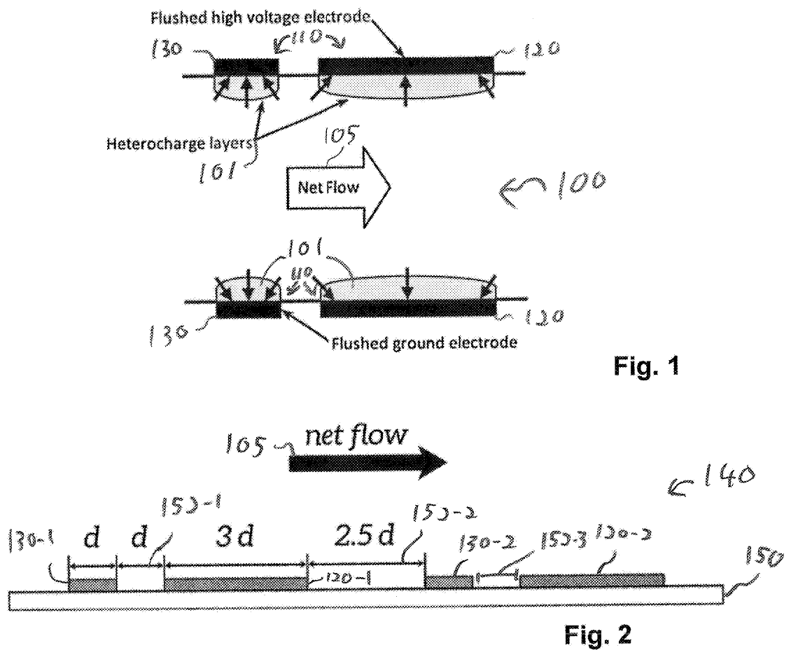

FIG. 1 is a diagram of electrohydrodynamic (EHD) force generation as employed in configurations herein. In FIG. 1, a schematic of an EHD conduction pumping mechanism 100 depicts the heterocharge layers 101 formed by electrodes 110 including high voltage electrodes 120, ground electrodes 130 and a net flow 105 direction. The alternating sequence of electrodes is configured to generate a net fluidic flow 105 of a dielectric fluid based on a voltage difference of the voltage electrodes 120 and the ground electrodes 130.

The forces generated by the EHD conduction pumping mechanism 100 are defined by electrohydrodynamics including Maxwell's equations for electromagnetism A system or mechanism 100 under the influence of EHD is considered electrically dominated, meaning that the magnetic field and its contribution is small. For dielectric liquids, this assumption is valid, as the magnetic field is related to the Ohmic current, which is very small in magnitude. Additionally, the low conductivity of dielectric liquids (on the order of 10⁻⁸ S/m) contributes to a substantially small current density. Under these conditions, Maxwell's equations can be reduced to:

$$∇ \cdot D = {ρ}_{e} \qquad ( 1.2 )$$

$$∇ \times E = 0 \qquad ( 1.3 )$$

$$\frac{\partial \text{?}}{\partial t} + ∇ \cdot J = 0 \qquad ( 1.4 )$$

$$∇ \times B = 0 \qquad ( 1.5 )$$

$$∇ \times H = J + \frac{\partial D}{\partial t} \qquad ( 1.6 )$$

$$\text{?} \text{indicates text missing or illegible when filed}$$

Where B is the magnetic field, D is the displacement field, J is the current density, His the magnetizing field, and E is the electric field.

The EHD body force is described in Equation (1.1). In a liquid, the DEP and electrostriction force are negligible, reducing this body force to a relationship between the applied electric field and charge concentrations, such that:

F_{EHD}=(pₑ−nₑ)E (1.7)

where p and n are the positive and negative charge densities, respectively. These are related to the ionic impurities described earlier through ionic concentration via the elementary charge, e₀.

pₑ=e₀p (1.8)

nₑ=e₀n (1.9)

Here, p and n are the positive and negative ionic concentrations, respectively. Ionic transport is represented by the Nernst-Planck equations:

∇·[−D∇p−K₊p∇φ]+u·∇p=Rₙ (1.10)

∇·[−D∇n−K₋p∇φ]+u·∇n=Rₙ (1.11)

where K+ and K− are the ionic mobilities of positive and negative species, D is the diffusion coefficient, and Rn is a reaction term associated with ionic species within the fluid. For EHD conduction pumping, the ionic mobility of the positive and negative ions is assumed to be equal, such that K+=K−=K. While this is not necessarily the case in actual dielectric liquids, the effect of mobility is not considered in this work, but it has been explored by previous studies. The diffusion coefficient is defined using the Stokes-Einstein relation for charged particles:

$$D = \frac{K {k}_{b} T}{{ε}_{0}} \qquad ( 1.12 )$$

where kb is the Boltzmann constant and T is absolute temperature. The reaction term in Equations (1.10) and (1.11) is equivalent in both equations:

Rₙ=k_{D}n_{eq}−k_{R}np (1.13)

where kD and kR represent the constants associated with dissociation and recombination, respectively, and n_{eq} is the equilibrium charge concentration in the absence of a significantly strong electric field. In the case of no electric field, this term reduces to zero. Furthermore, the dissociation and recombination constants in an equilibrium condition are expressed by:

$${k}_{D , eq} = {k}_{R} = \frac{2 K {e}_{0}}{ε} \qquad ( 1.14 )$$

Under a significantly strong enough electric field, the rate of dissociation exceeds that of recombination, as mentioned previously. This so-called enhanced dissociation is expressed as a rate constant.

k_{D}=F(ωₑ)k_{D,eq} (1.15)

The dissociation rate is multiplied by the Onsager field enhancement function:

$$F ( \text{?} ) = \frac{{I}_{1} ( 4 {ω}_{e} )}{2 {ω}_{e}} \qquad ( 1.16 )$$

$${ω}_{e} = \sqrt{( \frac{{( \text{?} )}^{3} \vert E \vert}{16 π \text{?} {k}_{b}^{2} {T}^{2}}} \qquad ( 1.17 )$$

$$\text{?} \text{indicates text missing or illegible when filed}$$

By replacing the equilibrium dissociation term in Equation (1.13) with the enhanced dissociation rate, Equation (1.13) can be rewritten:

$${R}_{n} = \frac{2 {Ke}_{0} {n}_{eq}^{2}}{ε} ( F ( {ω}_{e} ) - \frac{np}{{n}_{eq}^{2}} ) \qquad ( 1.18 )$$

This field enhanced dissociation is one of the driving factors of EHD conduction pumping. In terms of electrostatics, Poisson's equation factors in the charge density, and is expressed as:

$$∇ \cdot E = - ∇ {φ}^{2} = \frac{{ρ}_{e}}{ε} = \frac{{p}_{e} - {n}_{e}}{ε} \qquad ( 1.19 )$$

where φ is the electric potential, and ε is the electrical permittivity of the working fluid.

The Navier-Stokes equations define the hydrodynamic aspect of EHD conduction pumping via conservation of mass and momentum in an incompressible, dielectric fluid:

$$\frac{\partial ρ}{\partial t} + ∇ \cdot ( ρ u ) = 0 \qquad ( 1.2 )$$

$$ρ ( \frac{\partial u}{\partial t} + u \cdot ∇ u ) = - ∇ P + μ {∇}^{2} u + {F}_{EHD} \qquad ( 1.21 )$$

where F_{EHD} is the EHD body force defined in Equations (1.1) and (1.7), ρ is the fluid density, P is the pressure, u is the fluid velocity field, and μ is the fluid dynamic viscosity.

The energy equation is typically ignored when modeling EHD conduction pumping, but it is necessary when considering the heat generated by Joule heating. While Joule heating is negligible on large scales, its impact is more significant as smaller scales (i.e., micro-scale) are considered. The energy equation is defined as:

$$ρ {c}_{p} ( \frac{\partial T}{\partial t} + u \cdot ∇ T ) = ∇ \cdot ( k ∇ T ) + J \cdot E + {φ}_{v} \qquad ( 1.22 )$$

where cₚ is the fluid specific heat, Tis the absolute temperature of the fluid, k is the thermal conductivity of the fluid, J is the current density, E is the applied electric field, and φv is the viscous dissipation. The current density, specifically, is caused by the motion of ionic species in the fluid, such that:

J=ze₀(K₊p+K₋n)E−ze₀(D₊Δp+D₋Δn) (1.23)

The above derivations are based on model continuum. Continuum mechanics is based on the physical scale of the model in question, and it is defined by the Knudsen number:

$${K}_{n} = \frac{{λ}_{m}}{d} \qquad ( 1.24 )$$

Where λₘ is the mean free path of the fluid, and d is the characteristic length scale of the fluidic system. For EHD conduction pumping, the characteristic length is simply the distance between adjacent positive and negative electrodes. If Kₙ is sufficiently small (<0.1), a system can be considered as continuum fluid flow. Clearly, if the characteristic length is reduced to a very small scale, Kₙ can exceed a value of 10, leading to free molecular flow. When fluid flow in the absence of EHD is considered, the mean free path of fluid molecules is on the order of nanometers. However, when EHD is considered, the mean free path of ionic species must be considered. Length scales to consider when EHD is present include the Debye length, which is defined as the length scale of electrolytic solutions in the fluid, which is representative of the ions in the fluid. This value is dependent on fluid properties and fluid temperature, but it is typically around 1.5 μm in HFE-7100 at 15° C. Furthermore, the Bjerrum distance can be considered.

$${l}_{B} = \frac{{e}^{2}}{4 π ε {k}_{B} T} \qquad ( 1.25 )$$

This represents the distance at which the electrostatic energy between ions is equal to their thermal energy. Again, for HFE-7100 at 15° C., this distance is around 8 nm. Despite these, the mean free path of ionic species is dependent the recombination with opposite polarity species, which is based on the applied electric field. Due to a high enough electric field, ionic species may travel significant distances before recombining into neutral species, with estimates at 100 μm for a field strength of 4e6 V/m. Estimating the mean free path as the Debye length, the characteristic length of EHD electrodes would need to be between 10-20 μm. At this scale, the applied voltage necessary to induce a high enough field would be on the order of 50-100V, as opposed to kV, which is typically the order of applied potential of meso and macro-scale pumps. Additionally, despite EHD conduction pumping's ability to be scaled to both large and small scales, an operational limit exists when considering electrodes smaller than the micro-scale. At a small enough scale (i.e., the Debye length), a phenomenon such as electric field screening occurs, which describes the damping of the applied electric field as a result of mobile charge carriers (i.e., ions). Furthermore, at such a small scale, the availability of ionic species necessary to produce motion from EHD conduction pumping is severely limited in quantity compared to larger scales. Despite this, most applications of EHD conduction pumping have not designed pumps at the Debye length scale, and thus, pumping is achievable.

Configurations herein extend the EHD driven fluid mechanics described above with a bidirectional approach complemented by oscillating electrical control and a flexible form factor for implementing an EHD driven cooling approach in various settings and clearances. In conventional approaches, EHD conduction pumps were designed to operate in a single direction. In contrast, configurations herein disclose the fluid flow enhancement offered by a two-directional EHD conduction pump, which can allow for increased vorticity and oscillation as a result of the electrode design and the by applying a pulsating potential. In modern thermal management, oscillatory flow has become very relevant with regards to enhancing heat transfer. This is especially true for high power electronics applications, as well as space technologies.

The EHD approach may be complemented by dielectrophoresis (DEP), a phenomenon present in electrically driven flow, mostly present when there is either a liquid-vapor interface or a strong temperature gradient. The gradient of electrical permittivity is strongest at an interface, and this is utilized to enhance boiling of a dielectric liquid. It was found that the maximum critical heat flux (CHF) value was approximately three times higher than the observed CHF under the influence of no electric field.

Conventional approaches have generally been conducted on rigid pumping substrates or in rigid configurations. The disclosed configurations employ flexible EHD conduction pumps, designed to have the comparable length scale and characteristic length of previous rigid pumps, and they may be fabricated using materials including PET (Polyethylene Terephthalate) as a flexible substrate, then depositing a silver conductive ink in the shape of the electrodes in a process such as silk-screen printing. This process proves to be simpler and more cost-effective than the manufacturing methods used to make previous rigid pumps.

FIG. 2 is a schematic diagram of spacing of electrodes as in FIG. 1, and illustrates a demonstrative configuration. The novel, flexible EHD pump 140 design may be formed utilizing a silk-screen printing process. This method forces ink through a stencil on a porous material onto a substrate. The pumps were made using a silver conductive ink that could adhere to an electronic printing polyester substrate 150. Both the resistivity and conductivity are similar in magnitude to those of previous materials used in EHD conduction experiments. A typical silver conductive ink used to form electrodes has a resistivity of 3.81E-7 Ohm-m (1.5E-5 Ohm-in), and the polyester film has a resistivity of 1E17 Ohm-m (3.9E18 Ohm-in).

The flexible substrate 150 performs similar to rigid EHD conduction pumps structures. Asymmetric electrodes result in a net Coulomb force and flow, including the voltage electrodes 120-1 . . . 120-2 (120 generally) and ground electrodes 130-1 . . . 130-2 (130 generally). With these designs, the direction of the net Coulomb force goes from the ground electrode to the high voltage electrode. From left to right, FIG. 2 shows the ground electrode 130, high voltage and ground electrode spacing 152-1 . . . 152-3 (152 generally). A characteristic length d, defined as the spacing between the high voltage and ground electrodes of an electrode pair, determines the size of each electrode and a multiple spacing between pairs.

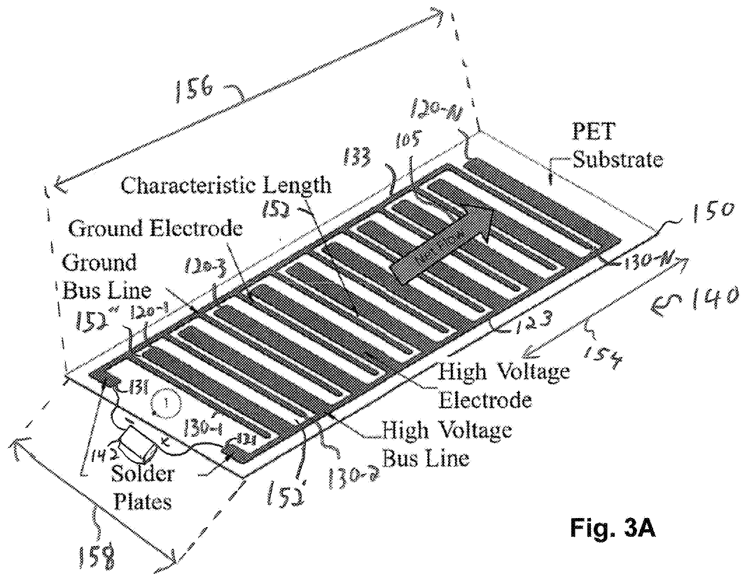

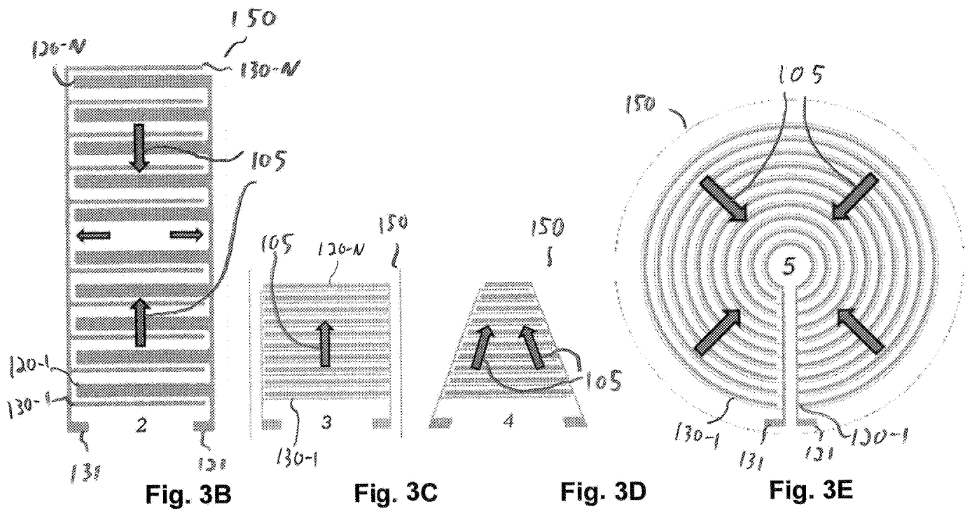

FIGS. 3A-3E shows EHD electrodes 110 on a substrate 150. The asymmetry of the electrodes 110 for providing the net flow 105 is shown, disposed or printed on the flexible substrate 150, optionally with a DEP electrode arrangement as disclosed in U.S. Pat. No. 12,324,128, issued Jun. 3, 2025, entitled “GRAVITY INDEPENDENT LIQUID COOLING FOR ELECTRONICS,” incorporated herein by reference in entirety.

Referring to FIGS. 1-3A, an electrohydrodynamic fluid transport device 140 as defined herein includes a plurality of voltage electrodes 120-1 . . . 120-N, and at least one ground electrode 130-1 . . . 130-N. Both the ground electrodes 130 and voltage electrodes 120 are aligned in an alternating sequence along a fluidic pumping path 105. An oscillation control 142 connect to terminals or solder plates 131 (ground bus) and 121 (high voltage bus) and is configured for applying an oscillating voltage signal to the voltage electrodes 120 at a predetermined frequency. The electrodes 120, 130 (collectively 110) are aligned in a linear arrangement 154 along the elongated substrate 150. The voltage electrodes 120 extend from the voltage bus 123 conductor extending along a length 156 of the elongated substrate 150. Similarly, the ground electrodes 130 extend from a ground bus 133 conductor extending along the length 156 on an opposed side of the substrate from the voltage bus 123 conductor.

The asymmetrically disposed, linear oriented electrodes 110 typically extend transverse across a width 158 of the elongated substrate 150 from a corresponding voltage bus 123 conductor or ground bus conductor 133, respectively. The electrodes 110 as shown extend a longer dimension widthwise on the substrate 150, with the voltage electrodes 120 being wider than the ground electrodes 130 to form the asymmetry. The electrodes 110 form an interleaving alternation along the length 156 of the substrate 150 and extend greater than half a width of the elongated substrate, typically extending almost completely transverse across the width 158 and terminating just short of the opposed bus 123, 133.

It should be further noted that each electrode 110 forms a spacing 152-N between adjacent electrodes, which is also asymmetric. In FIG. 3, the spacing 152′ (larger gaps) between the voltage electrode 120 to an adjacent ground electrode 130 in a direction of flow 105 is greater than a spacing 152″ (smaller gaps) between the voltage electrode 120 to an adjacent ground electrode 130 in a direction opposite to the flow. The wider voltage electrodes 120 extend a greater lengthwise distance along the length 156 of the substrate 150 than the ground electrodes 130 (narrower).

While the substrate 150 is shown as a flat planar structure, the substrate may be formed from a planar, flexible material and the electrodes 110 forming a layered planar arrangement on the substrate 150, either through printing of conductive ink or layering electrode strips. This forms a top surface of the electrodes flush with the others of the electrodes 110 when the printed traces or strips are substantially the same thickness, and possibly standing slightly proud of the substrate 150. Alternatively, the electrodes 110 may be embedded into recessed positions on the substrate 150 for forming a flush top surface between the substrate 150 and electrodes. 110.

FIGS. 3B-3E show alternative printed designs in addition to the macro view of FIG. 3A, including, a macro opposing (FIG. 3B), meso (FIG. 3C), nozzle (FIG. 3D), and radial (FIG. 3E). As noted, the pump designs in FIGS. 3A-3E differ in electrode configuration and size, as well as in the expected magnitude and type of flow that they will generate. The straight macro- and meso-scale pumps, as well as the radial pumps demonstrate flexible arrangements, and the opposing flow and nozzle pumps depict a more specialized mixing pump and converging flow accelerator, respectively. In these designs, the asymmetric electrodes result in a net Coulomb force and flow. With these designs, the direction of the net Coulomb force goes from the ground electrode to the high voltage electrode. While flat plane operation demonstrates a more balanced fluid distribution, flexed and non-level positions are also operable due to the flexible substrate 150.

In fluid pumping and distribution tests, initial testing of the flexible EHD conduction pumps were conducted with corn oil as a working fluid. Corn oil was selected because it is safe and easy to use, less toxic than refrigerants, and inexpensive to obtain, while still possessing the dielectric properties required for EHD pumping. A more practical application also includes experiments using the working fluids of Novec™ 7000 and Novec 7100 (HFE 7100).

The characteristic length for each pump is a determining factor for a voltage level applied to the pump. A greater distance between the ground and high voltage electrode allows for a higher voltage to be applied. Breakdown of the working dielectric fluid occurs when the fluid medium itself begins to dissociate at the fluid's rated breakdown voltage. This results in sparking on the pump, which is undesirable. Monitoring the current across the pump electrodes will allow for shutdown of the power supply before breakdown occurs.

In conventional approaches to oscillation heat transfer, devices such as OHPs (oscillating heat pipes) utilize oscillation to enhance heat transfer through local convection and latent heat transport between liquid and vapor phases present inside of the adiabatic section. An OHP, or pulsating heat pipe, is a passive, wickless two-phase heat transfer device. It consists of a meandering, capillary-sized tube filled with a working fluid that forms alternating liquid slugs and vapor bubbles. It moves heat through rapid pressure-driven pulsations and phase changes, offering high thermal conductivity. Such conventional approaches tend to be limited by mathematical complexity, unpredictability during startup, and passiveness as a heat transfer device. Furthermore, an oscillating bi-directional EHD conduction pump is numerically shown to be able to homogenize temperature distribution in a liquid channel, indicating enhanced heat transfer capabilities. Additionally, characteristics such as enhanced vorticity also support the proposition of EHD conduction pumping as a means of heat transfer enhancement in oscillating scenarios. Configurations herein demonstrate a flexible bi-directional EHD conduction pump for oscillating flow in the presence of liquid and vapor. The configurations herein provide a foundation to the use of EHD as a method of enhanced thermal management for electronics.

TABLE I

| | Measured EHD | Measured EHD | Measured EHD |
|---|---|---|---|
| Test Case | Voltage [VDC] | Current [μA] | Power [mW] |
| Baseline (no EHD) | 0 | 0 | 0 |
| 0 Hz 1500 VDC | 1493.38 | 28.93 | 43.20 |
| 2 Hz 1500 VDC | 1491.27 | 27.71 | 41.32 |
| 5 Hz 1500 VDC | 1493.62 | 28.64 | 42.78 |
| 9 Hz 1500 VDC | 1492.34 | 27.86 | 41.58 |
| 60 Hz 1500 VDC | 1492.83 | 28.51 | 42.56 |

Performance of the oscillating EHD conduction pump, as well as the heat transfer characteristics of the experiment are generated for a range of applied frequencies. A baseline operating voltage of 1500 VDC was employed, as depicted in Table I, and accordingly, the behavior of current as a function of applied voltage is not crucial. However, at various frequencies, due to the on/off nature of pulsating the applied potential, there was initial concern that current may be significantly higher at higher frequencies. Contrary to this, the measured current remained relatively consistent independent of applied frequency, indicating that these pumps can operate safely and predictably at various frequencies of pulsating high voltage. Table I displays the average voltage, current, and power consumption for a set of frequencies used in the disclosed configurations. As shown, the variation in measured voltage is quite small and within the error of the high voltage power supply used for the EHD conduction pump. The same trend exists for the current, where the maximum average current is for the 0 Hz (i.e., regular EHD conduction) pumping case at 28.93 μA. This case also experiences the maximum power consumption of 43.2 mW. The small scale of the power consumption is particularly notable, as it continues to highlight EHD's low power requirement, even when pulsating voltage is applied. It is important to note that these are average values during an entire test, and small (<5 μA) variations occur during testing.

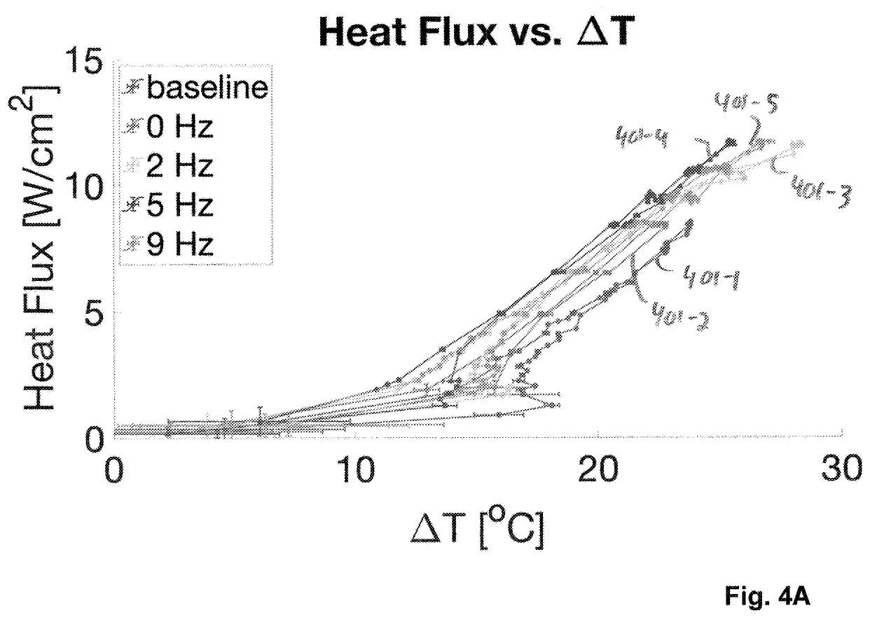

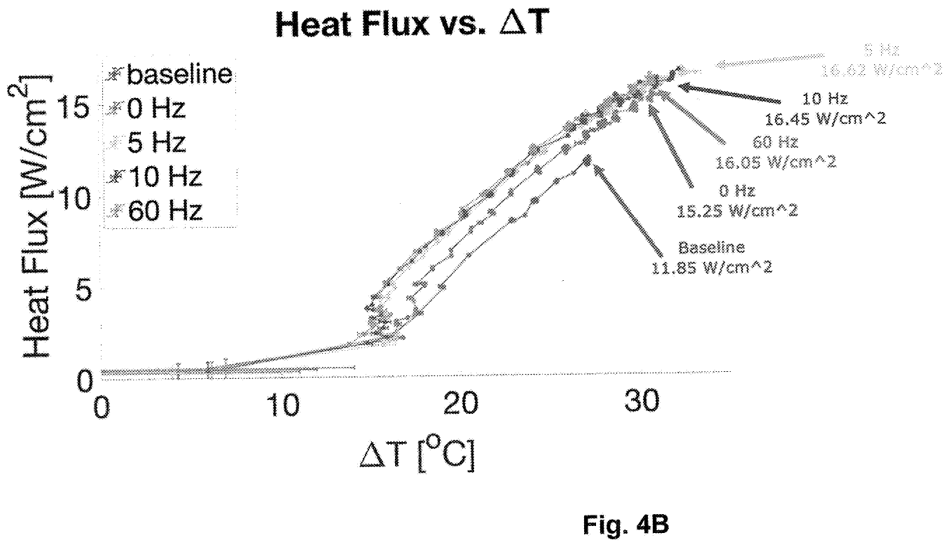

FIGS. 4A and 4B show heat flux suitable for electronics cooling using an EHD approach as in FIGS. 1-3. FIG. 4A shows the boiling curves for the cases of no electric field (i.e., baseline) 401-1, 0 Hz 401-2, 2 Hz 401-3, 5 Hz 401-4, and 9 Hz 401-5 cases. The temperature difference represents the difference between the heater surface temperature and the measured vapor temperature within the chamber. This is also referred to as the heater superheat. As can be seen by this result, the use of electric fields is beneficial for heat transfer. Comparing the baseline case to the 0 Hz case, an increase in the heat flux for a given ΔT is present for nearly all data points. Furthermore, the reduction in the ΔT value corresponding to the onset of nucleate boiling is also shown comparing the baseline and 0 Hz cases. The former reaches approximately 18° C. at 1.5 W/cm² before dropping to 16° C. as boiling begins. The 0 Hz case reaches a ΔT of 16° C. at 1.75 W/cm² at ONB. However, no significant drop in temperature at ONB is shown for the 0 Hz case. This is due to the EHD conduction pump being able to supply cooled liquid to the heater surface, delaying the ONB and reducing the associated ΔT drop. When comparing these cases to those involving applied potential at a frequency, the heat transfer enhancement becomes clear. In both the 2 Hz and 5 Hz cases, significant increases in heat flux for a given ΔT value are observed after ONB. The 5 Hz case in particular represents the best overall heat transfer of any frequency used in this study. At a heat flux of 5 W/cm², a ΔT drop of 3° C. is observed when comparing the baseline case to the 5 Hz case. This translates to heat transfer enhancement as the heater can operate at a given heat flux value for lower superheat. This also means that at a given ΔT value, the heater can reach higher heat fluxes. For the 9 Hz case, similar heat transfer behavior to the 2 Hz case can be observed. Comparing the baseline and 5 Hz cases, at a ΔT value of 18° C., an increase of 2.5 W/cm² in heat flux is observed. This translates to a heat flux enhancement of 62.5%. In terms of cooling of electronics, this would correspond to a heated CPU chip being able to operate at higher power densities (i.e., overclocking), while maintaining a lower temperature.

It should be noted that FIG. 4A represents tests in which the heater power was increased to a prescribed value and then decreased in increments down to zero. This type of test, as mentioned earlier, can capture the hysteresis effect present in boiling curves. This hysteresis is characterized by a noticeable difference in ΔT values when comparing cases where the heat flux is increasing and when it is decreasing. The baseline case captures this behavior most prominently. At a heat flux of 6 W/cm², the difference in ΔT values begins to appear. As the heat flux is decreased from this value, a larger and larger gap in ΔT is captured, remaining in the curve until power to the heater is returned to zero. This phenomenon exists for all cases considered but is reduced when oscillating EHD is applied. For these cases, the behavior is still very present, but only between 0 and 5 W/cm², and it does not have as large of a gap between increasing and decreasing ΔT values. For example, at 2 W/cm², this difference is 4° C. for the baseline case, whereas for the 0 Hz case at the same heat flux value, this difference is 2.5° C. For the 2 Hz and 5 Hz cases, this difference increases slightly to 3° C., however, this is still lower than that associated with the baseline case. For the 9 Hz case, this difference approaches 3.5° C. This trend implies that while oscillation can improve heat transfer, it is only able to marginally decrease effects associated with hysteresis. Alternative configurations may utilize the DEP force as a method of two-phase heat transfer enhancement, which is able to effectively eliminate the hysteresis altogether. Furthermore, in the baseline case, the hysteresis phenomenon starts during the reduction of heat flux at 5.75 W/cm², whereas the hysteresis corresponding to decreasing heat flux for the 0 Hz case start at 4.9 W/cm². The same trend is present in the 2 Hz, 5 Hz, and 9 Hz cases, with hysteresis occurring around 5 W/cm².

FIG. 4B shows similar boiling curves in cases where the tests were conducted at 2 kV and the heater was increased to a power high enough to reach critical heat flux. For the baseline case, CHF was 11.85 W/cm². Past this point, the heater was unable to maintain a stable temperature and tripped the 80° C. limit before shutting down. For the case of applied electric field, the trend in CHF enhancement is clear. For the 0 Hz case, the CHF was 15.25 W/cm², a 28.7% enhancement. The cases of 60 Hz, 10 Hz, and 5 Hz further increased the CHF values, with the 5 Hz case reaching the highest CHF value at 16.62 W/cm². This is an enhancement of 40.3% over the baseline case and an enhancement of 9% over the 0 Hz case. This enhancement is due to an ability to replenish the heater with cooled liquid from the condenser section at a given heat flux value. Furthermore, the enhancement due to oscillation is due to the combined effect of local convective enhancement along the pumping section, as well as enhancement due to the bubble departure frequency. Additionally, when considering the baseline case, the driving force behind cooling the heater with liquid from the condenser is purely from hydrostatic pressure. When EHD conduction pumping, additional pressure generation from the pump (generally on the order of 20-50 kPa) contributes to the increase in critical heat flux.

The configurations of FIGS. 3A-4B demonstrate that oscillating liquid film flow can be achieved via a bi-directional EHD conduction pump with pulsating potential. By pumping at various imposed frequencies, increases in both heat transfer coefficient and critical heat flux were observed, with the 5 Hz case performing the best of any frequency tested. The 5 Hz experienced a maximum enhancement in heat transfer in terms of heat flux for a given ΔT of 62.5% compared to the baseline case and an enhancement of 28.7% in terms of critical heat flux compared to the baseline case when operated at 2 kV. The mechanism behind this enhancement relies on the combined effect of enhanced local convection due to vorticity near the electrodes and the relationship between operating frequency and bubble departure frequency, especially near the ONB. Furthermore, the effect of frequency on liquid film flow is captured by PIV measurements. The 0 Hz case PIV results accurately capture the vortices near the electrodes, and they match well with previous numerical results. The effect of frequency shows that the vortices are smaller with increasing frequency.

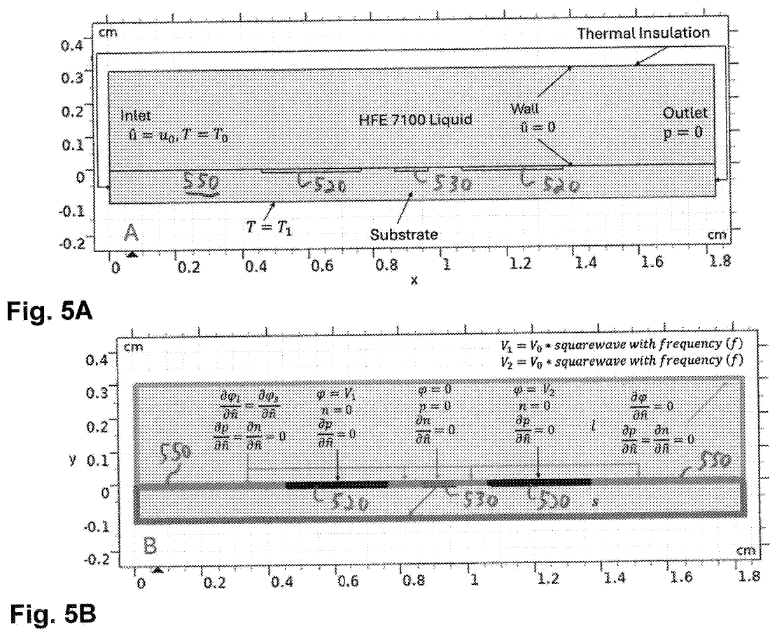

FIGS. 5A-5B show a schematic of a bidirectional EHD pump using electrodes as in FIGS. 1-4B. In FIGS. 5A-5B, the oscillating flow generated by the disclosed approach provides enhanced cooling for heated surfaces such as electronics. A beneficial feature of this EHD conduction pump is the design of the electrodes to pump in two directions at independent potentials. Therefore, the pump for this numerical study operates at pulsating DC voltages. The effect of frequency is discussed in the results. The operating frequency considered for this study ranges from 0-60 Hz with additional higher frequencies considered for heterocharge layer morphology evaluation. The results obtained support the use of bi-directional, oscillating EHD conduction pumping for heat transfer enhancement of next generation electronic devices.

In most conventional approaches, EHD conduction pumps were designed to operate in a single direction, however configurations herein demonstrate the enhancement offered by a two-directional EHD conduction pump, which can allow for increased vorticity and active oscillation as a result of the electrode design. In general, it is expected that bidirectionality may be achieved using EHD induction pumping heat transfer enhancement as a function of applied frequency between 0-12 Hz, finding that 5 Hz and 8 Hz offered the best heat transfer enhancement in a flat configuration. Further enhancement was achieved by tilting the pump at various angles between 0-90°.

FIGS. 5A and 5B show numerical domain highlighting thermal and hydrodynamic boundary conditions (FIG. 5A) and electrical boundary conditions (FIG. 5B), where the high voltage electrodes 520, ground electrodes 530, outer containment wall 501, and the substrate 550 sections are shown.

The two high voltage electrodes are operated independently of each other and represent a portion of the electrode setup that would be cascaded over a full-length pumping section. Since they are on either side of the common ground electrode, the pumping direction of one high voltage electrode is opposite of the other, with the left-side electrode pumping left and the right-side electrode pumping to the right. This, in combination with the fact that each high voltage electrode is operated at a given frequency consecutively, contributes to oscillations in the liquid. The two electrodes are operated at the same voltage magnitude. To evaluate the impact of oscillation frequency, several frequencies were chosen. The frequencies mainly evaluated are 0 Hz, 5 Hz, 10 Hz, and 60 Hz. Additional frequencies are considered for specific sets of results, such as the heat transfer coefficient.

While the system and methods defined herein have been particularly shown and described with references to embodiments thereof, it will be understood by those skilled in the art that various changes in form and details may be made therein without departing from the scope of the invention encompassed by the appended claims.

What is claimed is:

1. An electrohydrodynamic fluid transport device, comprising:
a plurality of voltage electrodes,
at least one ground electrode,
the ground electrodes and voltage electrodes aligned in an alternating sequence along a fluidic pumping path, and
an oscillation control configured for applying an oscillating voltage signal to the voltage electrodes at a predetermined frequency.

2. The device of claim 1 wherein the electrodes are aligned in a linear arrangement along an elongated substrate,
the voltage electrodes extending from a voltage bus conductor extending along a length of the elongated substrate,
the ground electrodes extending from a ground bus conductor extending along a length on an opposed side of the substrate from the voltage bus conductor.

3. The device of claim 2 wherein the electrodes extend transverse across a width of the elongated substrate from a corresponding voltage bus conductor or ground bus conductor, respectively.

4. The device of claim 3 wherein the electrodes form an interleaving alternation along the length of the substrate and extend greater than half a width of the elongated substrate. extend transversely.

5. The device of claim 3 wherein the electrodes form a spacing between adjacent electrodes, the spacing between a voltage electrode to an adjacent ground electrode in a direction of flow being greater than a spacing between the voltage electrode to an adjacent ground electrode in a direction opposite to the flow.

6. The device of claim 5 wherein the voltage electrodes extend a greater distance along the length of the substrate than the ground electrodes.

7. The device of claim 1 wherein the substrate is a planar, flexible material and the electrodes form a layered planar arrangement on the substrate, a top surface of the electrodes flush with the others of the electrodes.

8. The device of claim 1 wherein the alternating sequence of electrodes is configured to generate a fluidic flow of a dielectric fluid based on a voltage difference of the voltage electrodes and the ground electrodes.

9. The device of claim 1 wherein the oscillation control is configured to apply an oscillating voltage at a frequency between 0 and 60 Hz.

10. The device of claim 1 wherein the oscillation control is configured to apply an oscillating voltage up to 1500V.

11. A method of electrohydrodynamic fluid transport, comprising:
forming a sequence of electrodes including an alternating arrangement of voltage electrodes and ground electrodes;
disposing the electrodes in a fluidic pumping path; and
applying a voltage level in an oscillating manner to the voltage electrodes at a predetermined frequency.

12. The method of claim 11 further comprising applying an oscillating voltage at a frequency between 0 and 60 Hz to the voltage electrodes and the ground electrodes.

13. The method of claim 11 further comprising applying a voltage in a range between 0-1500V to the voltage electrodes.

14. The method of claim 11 wherein the electrodes are aligned in a linear arrangement along an elongated substrate,
the voltage electrodes extending from a voltage bus conductor extending along a length of the elongated substrate,
the ground electrodes extending from a ground bus conductor extending along a length on an opposed side of the substrate from the voltage bus conductor.

15. A fluidic transport system, comprising:
a plurality of voltage electrodes,
at least one ground electrode,
the ground electrodes and voltage electrodes aligned in an alternating sequence along a fluidic pumping path, and
an oscillation control electrically coupled to the voltage electrodes and ground electrode and configured for applying an oscillating voltage signal to the voltage electrodes at a predetermined frequency.
